(19) United States
(12) Patent Application Publication
(10) Pub. No.: US 2007/0163770 A1
(43) Pub. Date: Jul. 19, 2007

(54) Combination of heat pipe and heat sink and method thereof

(75) Inventors: Ko-Pin Liu, Taipei County (TW); Chun-Huang Chou, Taipei County (TW)

Correspondence Address: BACON & THOMAS, PLLC, 625 SLATERS LANE, FOURTH FLOOR, ALEXANDRIA, VA, 22314, US

(73) Assignee: TAI-SOL ELECTRONICS CO., LTD., TAIPEI CITY (TW)

(21) Appl. No.: 11/486,211

(22) Filed: Jul. 14, 2006

(30) Foreign Application Priority Data
Jan. 13, 2006 (TW) 95101504

(51) Int. Cl. H05K 7/20

(52) U.S. Cl. 165/185; 361/700; 257/715; 29/890.032

(57) ABSTRACT

A method of combination of a heat pipe and a heat sink includes the steps of preparing a heat sink and a heat pipe, wherein the heat sink has an insertion hole in which the heat sink is inserted; placing the heat sink and the heat pipe onto a carrier, wherein a pressing member is located over the carrier, and a convexity corresponds to the insertion hole; punching the heat sink with the pressing member by punching the insertion hole with the convexity to cause deformation of the sidewall of the insertion hole between the heat pipe and the heat sink, whereby the heat pipe is tightly fitted in the insertion hole; and removing the pressing member from the heat sink to complete the combination of the heat pipe and the heat sink.

### BACKGROUND OF THE INVENTION

1. Field of the Invention

The present invention relates generally to heat-dissipating apparatuses, and more particularly, to a combination of a heat pipe and a heat sink and a method thereof.

2. Description of the Related Art

A large number of conventional methods of the combination of a heat sink and a heat pipe had been disclosed in the prior art. For example, Taiwan Patent No. M268112 entitled “COMBINATION OF HEAT SINK AND HEAT PIPE HELD TIGHT BY PUNCH” disclosed a combination of a heat sink and a heat pipe that the fins are pressed toward the base by punch to enable external expansion and deformation of the fins and the base to be held tight with each other such that the heat pipe is tightly mounted between the fins and the base.

In addition, there is another structure that the heat sink has an insertion hole for inserting the heat pipe therein, as so-called loose-fit connection. However, the outer sidewall of the heat pipe and the sidewall of the insertion hole fail to be in perfectly close contact with each other such that the contact area between them is not large enough to cause effective thermal conduction. Further, the heat pipe is subject to slipping away from the insertion hole, and thus, solder is generally mounted between the outer sidewall of the heat pipe and the sidewall of the insertion hole for enlarging the contact area therebetween to enhance the thermal conductivity while heated after the heat pipe is inserted into the insertion hole.

In light of above, there is still much space for improvement of the aforementioned drawbacks.

### SUMMARY OF THE INVENTION

The primary objective of the present invention is to provide a combination of a heat pipe and a heat sink and a method of the combination, which enlarges the contact area between the heat pipe and the heat sink, after they are combined together, to further enhance the thermal conductivity.

The foregoing objective of the present invention is attained by the method including the steps of preparing a heat sink and a heat pipe, wherein the heat sink has an insertion hole in which the heat sink is inserted; placing the heat sink and the heat pipe onto a carrier, wherein a pressing member is located over the carrier, and a convexity corresponding to the insertion hole is formed among the pressing member, the heat sink, and the carrier; punching the heat sink with the pressing member by punching the insertion hole with the convexity to cause deformation of the sidewall of the insertion hole between the heat pipe and the heat sink, whereby the heat pipe is tightly fitted in the insertion hole; and removing the pressing member from the heat sink to complete the combination of the heat pipe and the heat sink.

The foregoing objective of the present invention is also attained by the combination structurally composed of a heat sink and a heat pipe. The heat sink has an insertion hole. The heat pipe is inserted in the insertion hole. The sidewall of the insertion hole between the heat pipe and the heat sink is deformed to enable the heat pipe to be tightly fitted in the insertion hole.

### BRIEF DESCRIPTION OF THE DRAWINGS

FIG. 1 is a block diagram of a first preferred embodiment of the present invention.

FIG. 2 is a schematic view of the first preferred embodiment of the present invention in operation.

FIG. 3 is another schematic view of the first preferred embodiment of the present invention in operation.

FIG. 4 is another schematic view of the first preferred embodiment of the present invention in operation.

FIG. 5 is a schematic view of a second preferred embodiment of the present invention in operation.

FIG. 6 is another schematic view of the second preferred embodiment of the present invention in operation.

FIG. 7 is a schematic view of a third preferred embodiment of the present invention in operation.

FIG. 8 is another schematic view of the third preferred embodiment of the present invention in operation.

FIG. 9 is another schematic view of the third preferred embodiment of the present invention in operation.

FIG. 10 is another schematic view of the third preferred embodiment of the present invention in operation.

### DETAILED DESCRIPTION OF PREFERRED EMBODIMENTS

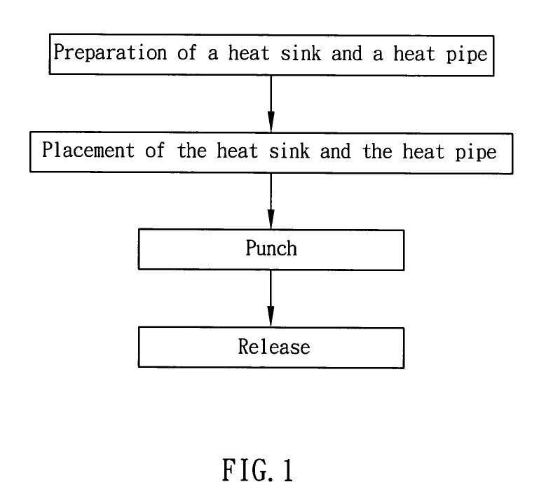

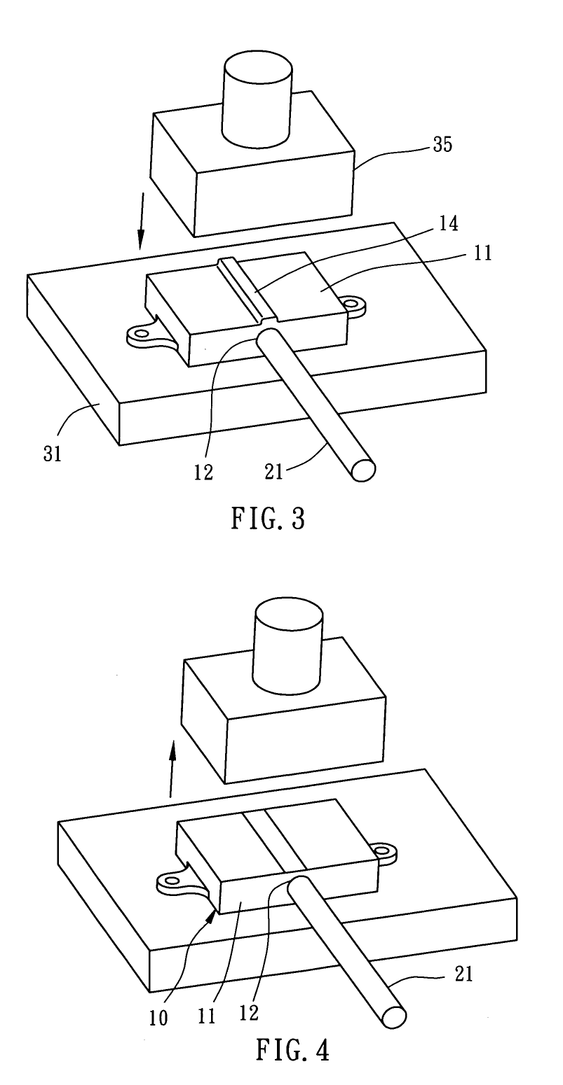

Referring to FIGS. 1-4, a method of combination of a heat pipe and a heat sink, based on a first preferred embodiment of the present invention, includes the following steps.

A. Preparation of a Heat Sink and a Heat Pipe

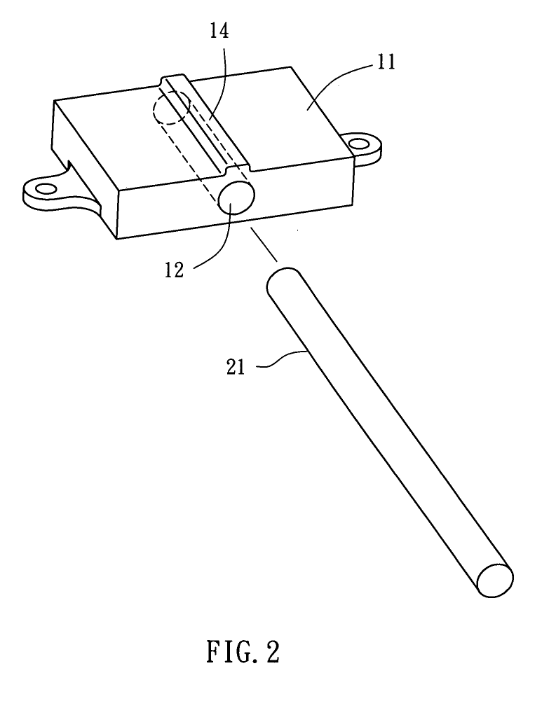

Prepare a heat sink 11 and a heat pipe 21, as shown in FIG. 2. The heat sink 11 has an insertion hole 12. The heat pipe 21 is inserted into the insertion hole 12.

B. Placement of the Heat Sink and the Heat Pipe

Place the heat sink 11 together with the heat pipe 21 onto a carrier 31. A pressing member 35 is located over the carrier 31. The heat sink 11 has a convexity 14 formed on a top side thereof and located on the insertion hole 12 to correspond thereto.

C. Punch

Punch the heat sink 11 with the pressing member 35 by punching the insertion hole 12 with the convexity 14 to cause deformation of the sidewall of the insertion hole 12 between the heat pipe 21 and the heat sink 11 to further enable the heat pipe 21 to be tightly held in the insertion hole 12.

D. Release

Remove the pressing member 35 from the carrier 31, as shown in FIG. 4, to complete the combination 10 of the heat pipe 21 and the heat sink 11.

In addition, it is to be noted that the heat sink 11 in the step B can alternatively be upside-down on the carrier 31 for taking punch; the convexity 14 can alternatively be formed on the carrier 31 for punch. These changes and modifications belong to equivalents of the present invention, such that no tautological recitation is necessary.

Referring to FIG. 4 again, the combination 10 constructed according to the first preferred embodiment of the present invention is composed of the heat sink 11 and the heat pipe 21. The heat sink 11 has the insertion hole 12. The heat pipe 21 is inserted into the insertion hole 12. The sidewall of the insertion hole 12 between the heat pipe 21 and the heat sink 11 is deformed to enable the heat pipe 21 to be tightly held in the insertion hole 12.

Referring to FIG. 5, a method of combination of a heat pipe and a heat sink, based on a second preferred embodiment of the present invention, is similar to the first embodiment but different by that the convexity 14′ is formed at a bottom side of the pressing member 35′ in the step B.

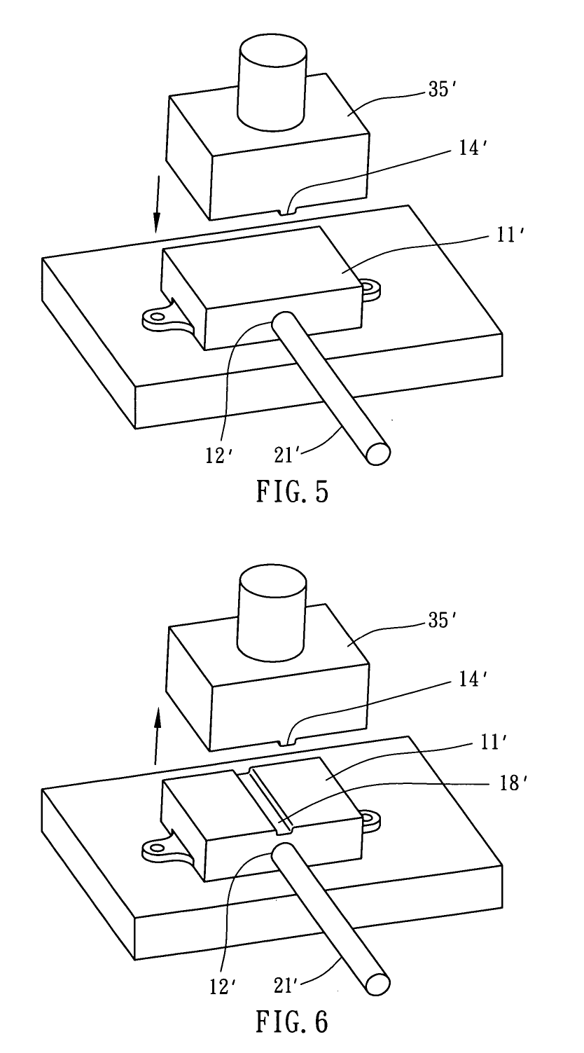

FIG. 6 shows the finished product after the step D in the second embodiment of the present invention. Because the convexity 14′ is located at the bottom side of the pressing member 35′, a ditch 18′ corresponding to the convexity 14′ is formed on the heat sink 11′ after punch of the pressing member 35′ with the convexity 14′. Therefore, the second embodiment is the same as the first one that the sidewall of the insertion hole 12′ between the heat sink 11′ and the heat pipe 21′ is deformed to tightly hold the heat pipe 21′.

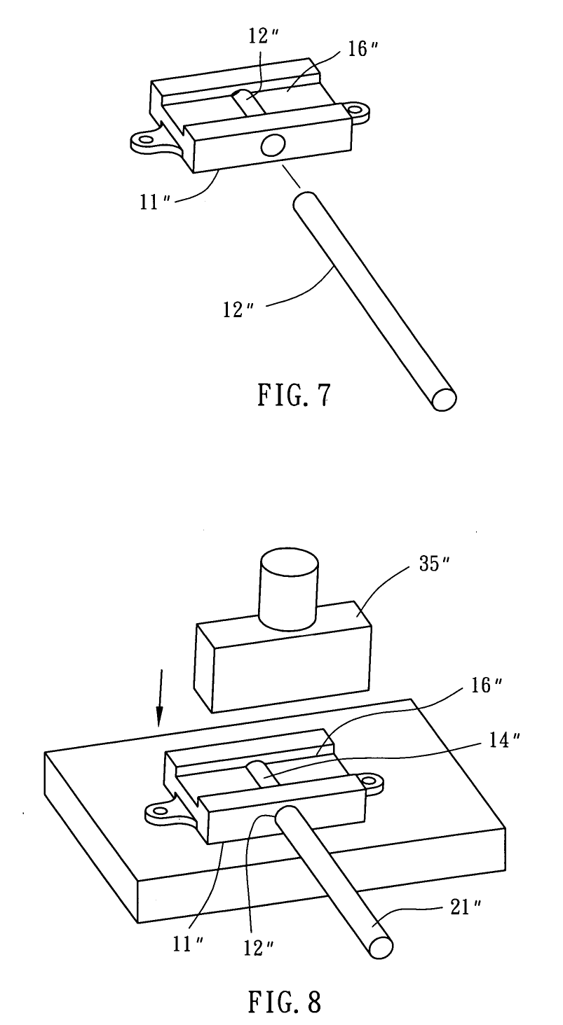

Referring to FIG. 7, a method of combination of a heat pipe and a heat sink, based on a third preferred embodiment of the present invention, is similar to the first embodiment but different as recited below.

In the step A, the heat sink 11″ further has a recessed portion 16″. The recessed portion 16″ partially overlaps the insertion hole 12″ to communicate with the insertion hole 12″. The heat pipe 21″ inserted in the insertion hole 12″ has a part protruding from the recessed portion 16″.

In the step B, as shown in FIG. 8, the part of heat pipe 21″ that protrudes from the recessed portion 16″ is defined as the convexity 14″.

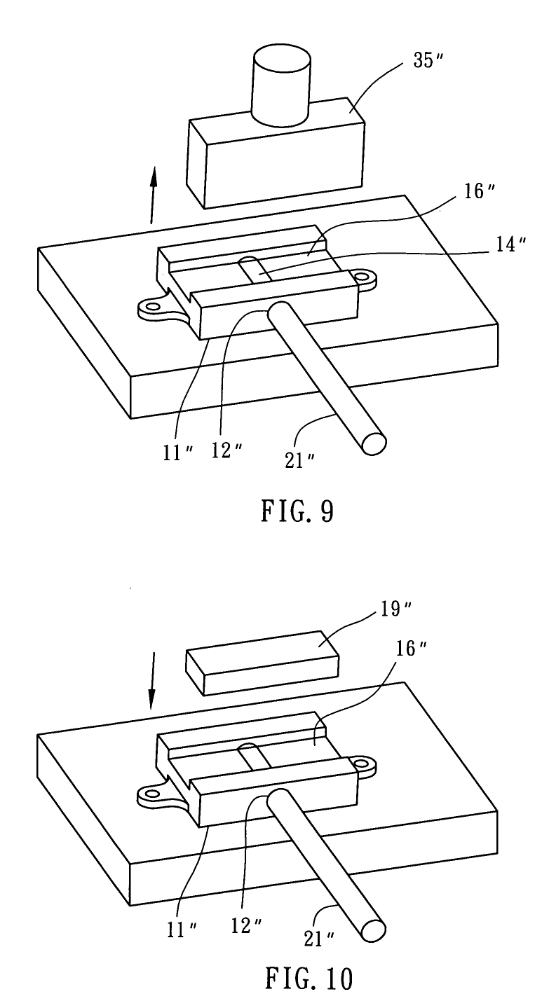

In the step C, the pressing member 35″ punches the convexity 14″ to enable a tip side of the convexity 14″ to be located at the same level as a bottom side of the recessed portion 16″. Thus, the heat pipe 21″ is deformed along with the insertion hole 12″ to be tightly held in the insertion hole 12″, as shown in FIG. 9.

The third embodiment further includes another step as follows.

E. Additional Thermal Conductive Member Mounted

Weld a thermal conductive member 19″, which can be a copper brick, into the recessed portion 16″ and to the surface of the heat pipe 21″, as shown in FIG. 10. In this step, the protruding part of the heat pipe 21″ has been punched to be flat such that the heat pipe 21″ has larger surface area for contact with the heat sink 19″. Thus, the heat being conducted by the heat pipe 21″ is directly transmitted to the heat sink 19″, or the heat in the thermal conductive member 19″ is directly transmitted to the heat sink 11″ through the heat pipe 21″, having the same excellent thermal conduction.

As indicated above, the present invention has an advantage of enlarging the contact area between the heat sink and the heat pipe after they are combined together, especially the contact area between sidewalls of the heat pipe and the insertion hole respectively, for enhancing the thermal conductivity.

Although the present invention has been described with respect to specific preferred embodiments thereof, they are no way limited to the details of the illustrated structures but changes and modifications may be made within the scope of the appended claims.

What is claimed is:

1. A method of combination of a heat pipe and a heat sink, comprising steps of:
(A) preparing a heat sink and a heat pipe, wherein said heat sink has an insertion hole and said heat pipe is inserted into said insertion hole;
(B) placing said heat sink and said heat pipe onto a carrier, wherein a pressing member is located over said carrier and a convexity corresponding to said insertion hole is formed among said pressing member, said heat sink, and said carrier;
(C) punching said heat sink with said pressing member by punching said insertion hole with said convexity to cause deformation of a sidewall of said insertion hole between said heat pipe and said heat sink, whereby said heat pipe is tightly held in said insertion hole; and
(D) removing said pressing member to complete the combination of said heat sink and said heat pipe.

2. The method as defined in claim 1, wherein in the step (B), said convexity is formed on a top side of said heat sink and located above said insertion hole.

3. The method as defined in claim 1, wherein in the step (B), said convexity is formed at a bottom side of said pressing member.

4. The method as defined in claim 1, wherein in the step (A), said heat sink further comprises a recessed portion, said recessed portion partially overlapping said insertion hole to communicate with said insertion hole; said heat pipe inserted into said insertion hole has a part protruding from said recessed portion and being defined as said convexity in the step (B).

5. The method as defined in claim 4 further comprising a step (E) of mounting a thermal conductive member to said recessed portion and in contact with a surface of said heat pipe.

6. A combination of a heat pipe and a heat sink, comprising:
a heat sink having an insertion; and
a heat pipe inserted into said insertion hole;
wherein a sidewall of said insertion hole between said heat pipe and said heat sink is deformed to tightly hold said heat pipe in said insertion hole.
